(19) United States
(12) Patent Application Publication
(10) Pub. No.: US 2010/0187526 A1
(43) Pub. Date: Jul. 29, 2010

(54) SEMICONDUCTOR DEVICE AND METHOD FOR MANUFACTURING SAME

(75) Inventors: Kanji Egawa, Sendai (JP); Akihiro Zemba, Sendai (JP)

Correspondence Address: ONDA TECHNO Intl. Patent Attys., 12-1 Omiya-cho 2-chome, Gifu City, 500-8731, JP

(73) Assignee: FREESCALE SEMICONDUCTOR, INC, Austin, TX (US)

(21) Appl. No.: 12/613,543

(22) Filed: Nov. 6, 2009

(30) Foreign Application Priority Data
Jan. 29, 2009 (JP) 2009-017827

(51) Int. Cl. H01L 23/525; H01L 21/768

(52) U.S. Cl. 257/48; 438/601; 257/E23.149; 257/E21.592

(57) ABSTRACT

A semiconductor device semiconductor device allowing for use of a test circuit that withstands only low voltages and has a small circuit area. A high-voltage operational circuit, which is operated at a high voltage, is connected to first and second pads. A multiplexer used to test the high-voltage operational circuit is connected to a third pad in addition to the first and second pads. Fuses are arranged on wires connecting the first and second pads to the multiplexer. An inspection board connects the third pad to ground after testing the high-voltage operational circuit, provides a breakage signal to the multiplexer, and applies voltage to the first or second pad. The multiplexer, which receives the breakage signal, connects the first or second pad with the third pad so that current flows therebetween. This breaks the corresponding fuse and insulates the multiplexer from the high-voltage operational circuit.

### BACKGROUND OF THE INVENTION

The present invention relates to a semiconductor device, which includes a high-voltage circuit, and a method for manufacturing a semiconductor device.

When a semiconductor device is manufactured, an operational test is conducted on the semiconductor device to perform an operational check. In this case, a semiconductor device that incorporates a test circuit has been proposed to realize mass-production and simplify the operational test, as described in Japanese Laid-Open Patent Publication No. 2004-110935 (page 1 and FIG. 1). The semiconductor device of Japanese Laid-Open Patent Publication No. 2004-110935 includes a memory circuit for reading and writing data. A test circuit has first and second external terminals. The test circuit compares a read signal and a corresponding expected value, which are input to the first external terminal, with a comparison circuit. A latch circuit of the test circuit then retrieves the comparison result in synchronism with a determination strobe signal, which is input to the second external terminal.

A semiconductor device incorporating such a test circuit may include a high-voltage operational circuit operated with a voltage that is higher than the voltage used during testing. In this case, high voltages are applied to the test circuit, which is connected to the high-voltage operational circuit. Thus, the test circuit must withstand high voltages. Generally, for a test circuit to withstand high voltages, the test circuit area must be enlarged compared to when it is formed to withstand only low voltages. Thus, a test circuit that withstands high voltages enlarges the entire semiconductor device.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a schematic diagram showing a semiconductor device according to one embodiment of the present invention; and

FIG. 2 is a flowchart showing the procedures for manufacturing the semiconductor device of FIG. 1.

### DETAILED DESCRIPTION OF THE INVENTION

The present invention provides a semiconductor device that allows for use of a test circuit that withstands only low voltages and has a small circuit area, and a method for manufacturing such a semiconductor device.

One aspect of the present invention is a semiconductor device including an operational circuit. A test circuit conducts a test on the operational circuit. The operational circuit is operated at a voltage that is higher than a test voltage used by the test circuit. A wire breakage facilitation unit is arranged on part of a wire connecting the operational circuit and the test circuit to insulate the test circuit from the operational circuit. The wire breakage facilitation unit is connected to the operational circuit when the test circuit is being used to test the operational circuit and disconnected from the operational circuit when the operational circuit is not being tested.

A further aspect of the present invention is a method for manufacturing a semiconductor device including an operational circuit. A test circuit tests the operational circuit. The operational circuit is operated at a voltage that is higher than a test voltage used by the test circuit. A wire breakage facilitation unit is arranged on part of a wire connecting the operational circuit and the test circuit. The method includes breaking the wire breakage facilitation unit after the test circuit tests the operational circuit to insulate the test circuit from the operational circuit.

Other aspects and advantages of the present invention will become apparent from the following description, taken in conjunction with the accompanying drawings, illustrating by way of example the principles of the invention.

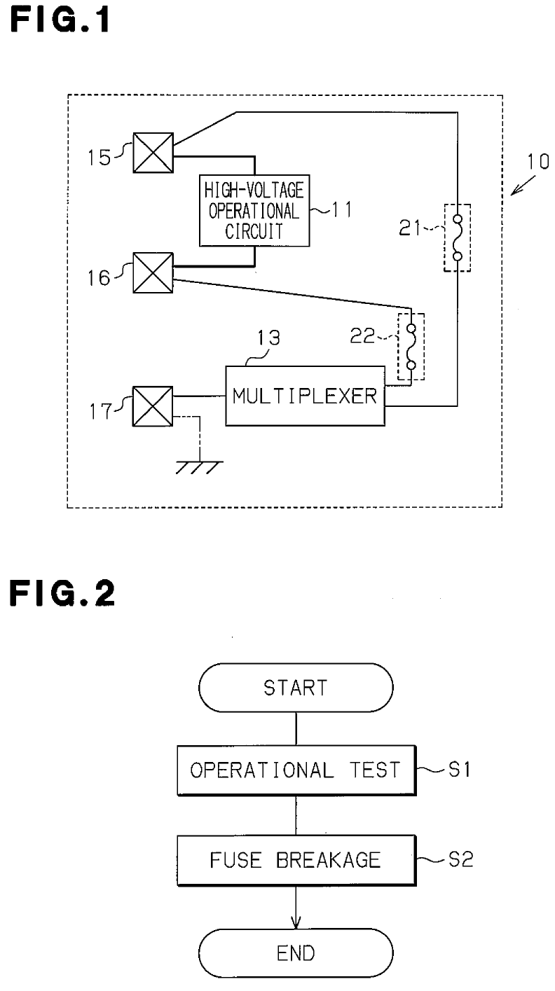

A semiconductor device 10 according to one embodiment of the present invention will now be discussed with reference to FIG. 1.

As shown in FIG. 1, the semiconductor device 10 includes a high-voltage operational circuit 11 and a multiplexer 13, which serves as a test circuit. The high-voltage operational circuit 11 and the multiplexer 13 are formed on the same chip or die.

In the present embodiment, the high-voltage operational circuit 11 performs a predetermined operation using a voltage (e.g., 0 V to 20 V) that is higher than the voltage used by the multiplexer 13 when conducting a test. Thus, the high-voltage operational circuit 11 uses semiconductor elements that can withstand high-voltage. The high-voltage operational circuit 11 is connected to pads 15 and 16, which serve as electrodes. The pads 15 and 16 can be connected to an external circuit that applies a voltage to the electrodes 16 and 16.

The multiplexer 13 functions as a test circuit for conducting an operational test on the high-voltage operational circuit 11. The multiplexer 13 conducts the test using a test voltage that is lower than the voltage used by the high-voltage operational circuit 11. Specifically, the multiplexer 13 is an analog multiplexer and receives a selection instruction signal and analog signals. The multiplexer 13 selects the analog signal to be received in accordance with the selection instruction signal and outputs the selected analog signal as an output signal.

In the present embodiment, the multiplexer 13 is connected to a pad 17 in addition to the pads 15 and 16. The multiplexer 13 is provided with an analog signal from an inspection board, which will be described later, or from the high-voltage operational circuit 11 via the pads 15 and 16. Further, the multiplexer 13 provides an output signal to the inspection board via the pad 17. The pad 17 may be connected to an external circuit via the inspection board so that voltage may be applied by the external circuit. The pad 17 functions as an electrode.

Further, the multiplexer 13 connects the pad 15 or pad 16 to the pad 17 when acquiring a breakage signal as the selection instruction signal from the inspection board. This forms an internal connection so that current flows between the pad 15 (or pad 16) and the pad 17. A first fuse 21 is provided between the multiplexer 13 and the electrode 15, and a second fuse 22 is provided between the multiplexer 13 and the electrode 16. The first fuse 21, which serves as a wire breakage facilitation unit, is arranged on a wire connecting the multiplexer 13 and the pad 15. The fuse 22, which serves as a wire breakage facilitation unit, is arranged on a wire connecting the multiplexer 13 and the pad 16. In this case, the current that flows is large enough to break the fuses 21 and 22.

[Manufacturing Method]

A method for manufacturing the semiconductor device of the present invention will now be described with reference to FIG. 2. Here, the processing subsequent to completion of the wiring of the semiconductor device 10 will be discussed.

First, an operational test is conducted (step S1). Specifically, terminals of an inspection board, which is known in the art, are connected to the pads 15 to 17 of the semiconductor device 10. A test generation signal, which is generated by the inspection board, is provided to the high-voltage operational circuit 11 via one of the pads 15 or 16. The inspection board also provides the selection instruction signal to the multiplexer 13. The multiplexer 13 acquires a signal from the high-voltage operational circuit 11 via the pads 15 and 16 and provides the signal to the inspection board via the pad 17. The inspection board conducts the operational test by checking whether or not the signal acquired from the pad 17 is the expected output signal.

When confirming in the operational test that the high-voltage operational circuit 11 is functioning normally, a fuse breakage process, which serves as a breakage step, is performed (step S2). Specifically, the inspection board, which has completed the test, connects the pad 17 to ground. Further, the inspection board performs wire selection by providing a breakage signal to the multiplexer 13. Here, the inspection board provides the breakage signal to the multiplexer 13 to break the fuse 21. The multiplexer 13, which receives the breakage signal, connects the wire connected to the pad 15 and the wire connected to the pad 17.

The inspection board then applies voltage to the pad 15, which is connected to the wire on which the fuse 21 is arranged. A current greater than the tolerable current of the fuse 21 flows through the wire on which the fuse 21 is arranged. This heats and breaks the fuse 21.

In this case, the inspection board monitors changes in voltage or current at the pad 15 to which voltage is applied. When the fuse 21 breaks and the inspection board detects a change in the voltage or current at the pad 15, the inspection board provides the multiplexer 13 with a breakage signal for breaking the fuse 22. In response to the breakage signal, the multiplexer 13 connects the wire connected to the pad 16 and the wire connected to the pad 17.

The inspection board then applies voltage to the pad 16, which is connected to the wire on which the fuse 22 is arranged. In the same manner as the fuse 21, a current greater than the tolerable current of the fuse 22 flows through the wire on which the fuse 22 is arranged. This breaks the fuse 22.

In this case as well, the inspection board monitors changes in voltage or current at the pad 16 to which voltage is applied. When the fuse 22 breaks and the inspection board detects a change in the voltage or current at the pad 16, the fuse breakage process is completed. This ends the manufacturing method of the semiconductor device 10.

The present embodiment has the advantages described below.

In the present embodiment, the high-voltage operational circuit 11 and the multiplexer 13 are connected to the pads 15 and 16. The fuses 21 and 22 are arranged between the multiplexer 13 and the pads 15 and 16. Thus, breakage of the fuses 21 and 22 insulates the multiplexer 13 from the high-voltage operational circuit 11. As a result, high voltage is not applied to the multiplexer 13 during operation of the high-voltage operational circuit 11. This allows for the multiplexer 13 to have a low withstand voltage and thereby allows for the multiplexer 13 to occupy a smaller area on a chip.

In the present embodiment, the fuse breakage (step S2) is performed after the operational test is completed. In this case, when receiving a breakage signal for breaking the fuse 21, the multiplexer 13 connects the wire that is connected to the pad 15 and the pad 17 that is connected to ground. Voltage is then applied to the pad 15 so that current flows through the wire on which the fuse 21 is arranged. This breaks the fuse 21. Next, when receiving a breakage signal for breaking the fuse 22, the multiplexer 13 connects the wire connected to the pad 16 and the wire connected to the pad 17, which is connected to ground. Voltage is then applied to the pad 15 so that current flows through the wire on which the fuse 21 is arranged. This breaks the fuse 22. Thus, the fuses 21 and 22 are easily broken by providing the breakage signal to the multiplexer 13, changing the connection of the multiplexer 13, and applying voltage to the pads 15 and 16.

It should be apparent to those skilled in the art that the present invention may be embodied in many other specific forms without departing from the spirit or scope of the invention. Particularly, it should be understood that the present invention may be embodied in the following forms.

In the above-described embodiment, the inspection board provides the multiplexer 13 with the breakage signal to connect the pad 17, which outputs the signal of the multiplexer 13 that serves as a test circuit, to ground. However, the present invention is not limited in such a manner, and the test circuit may be formed to include a wire that breaks the fuses 21 and 22 arranged between the test circuit and the high-voltage operational circuit 11 when receiving a breakage signal. For instance, if the test circuit includes a ground line, the test circuit may connect the wires of the fuses 21 and 22 to the ground line so that current flows to and breaks the fuses 21 and 22 when receiving the breakage signal.

In the above-described embodiment, the pad 17, which outputs the signal of the multiplexer 13, is connected to ground. Further, current flows to the wires of the fuses 21 and 22 to break the fuses 21 and 22. The breakage of the fuses 21 and 22 is not limited in such a manner. For instance, upon completion of the operational test, the fuses 21 and 22 may be broken by a laser beam when a fuse in the high-voltage operational circuit 11 is broken by a laser beam. Further, a pad connected to the fuses 21 and 22 but not to the multiplexer 13 may be used, and current may flow through wires connected to this pad and the pad 15 (16) to break the fuse 21 (22). In this case, there is no need for a large current to flow the multiplexer 13 in order to break the fuse 21 (22) to.

In the above-described embodiment, the fuses 21 and 22 are used as wire breakage facilitation units. However, the present invention is not limited in such a manner as long as the test circuit can be easily insulated from the high-voltage operational circuit 11.

In the above-described embodiment, the multiplexer 13 is connected to the high-voltage operational circuit 11 by two wires. Thus, the fuses 21 and 22 are each arranged on one of the wires. However, the location and quantity of fuses are not limited in such a manner as long as the multiplexer 13 can be insulated from the high-voltage operational circuit.

The present examples and embodiments are to be considered as illustrative and not restrictive, and the invention is not to be limited to the details given herein, but may be modified within the scope and equivalence of the appended claims.

What is claimed is:

1. A semiconductor device comprising:
an operational circuit;
a test circuit for conducting a test on the operational circuit, wherein the operational circuit operates at voltage that is higher than a test voltage used by the test circuit; and
a wire breakage facilitation unit, arranged on part of a wire connecting the operational circuit and the test circuit, for insulating the test circuit from the operational circuit, wherein the wire breakage facilitation unit is connected to the operational circuit when the test circuit conducts a test and disconnected from the operational circuit when the operational circuit operates.

2. The semiconductor device of claim 1, wherein the wire breakage facilitation unit is a fuse.

3. The semiconductor device of claim 2, further comprising:
a plurality of electrodes that are connectable to an external device and through which current that is large enough to break the fuse flows.

4. A method for manufacturing a semiconductor device including:
an operational circuit;
a test circuit for testing the operational circuit, wherein the operational circuit operates at higher voltage than the test circuit; and
a wire breakage facilitation unit arranged on part of a wire connecting the operational circuit and the test circuit;
the method comprising:
breaking the wire breakage facilitation unit after the test circuit tests the operational circuit, thereby insulating the test circuit from the operational circuit.

5. The method of claim 4, wherein:
the wire breakage facilitation unit is a fuse;
the test circuit, when receiving a breakage signal, connects a wire connected to the fuse and a wire connected to an electrode, which is connectable to an external device; and
said breaking the wire breakage facilitation unit includes:
providing the breakage signal to the test circuit; and
having current flow to the wire on which the fuse is arranged to break the fuse.
